(19) United States
(12) Patent Application Publication
(10) Pub. No.: US 2023/0203654 A1
(43) Pub. Date: Jun. 29, 2023

(54) SEMICONDUCTOR SUBSTRATE PROCESSING APPARATUS AND THE METHOD THEREOF

(71) Applicant: ASM IP Holding, B.V., Almere (NL)

(72) Inventors: Paridhi Gupta, Tempe, AZ (US); Taku Omori, Tokyo (JP); Cheuk Li, Chandler, AZ (US); Aadil Vora, Tempe, AZ (US); Todd Dunn, Cave Creek, AZ (US)

(21) Appl. No.: 18/147,631

(22) Filed: Dec. 28, 2022

Related U.S. Application Data
(60) Provisional application No. 63/294,610, filed on Dec. 29, 2021.

(51) Int. Cl. C23C 16/455; C23C 16/52

(52) U.S. Cl. CPC C23C 16/45544; C23C 16/52; C23C 16/45587

(57) ABSTRACT

Apparatus and method for semiconductor substrate processing are presented. For devices such as valves used for semiconductor substrate processing especially a process like ALD, there is a need to monitor and control the exact time taken from the signal to open and close the valves so that delay times may be controlled. In an embodiment, an apparatus comprising a reactor, a valve, a process controller and a valve monitor system is presented. The process controller may be operationally connected to the valve and may be provided with a memory. The sensors may be either electrical or optical sensors.

### FIELD OF INVENTION

The invention relates to an apparatus and method for processing semiconductor substrates more particularly to a semiconductor substrate processing apparatus.

### BACKGROUND OF THE DISCLOSURE

Semiconductor devices are commonly formed by depositing films onto substrates such as atomic layer deposition (ALD) techniques. ALD techniques generally employ providing flows of precursors to a process chamber cyclically for relatively short periods of time, e.g., on the order of milliseconds, to form a desired layer on an individual substrate.

The flows may be typically provided by high speed valves, which open and close according to a predetermined schedule defined in a “process recipe”, provided to a valve controller, and executed by cooperation of the valve controller and valves. The quality of the film deposited with the ALD technique may depend on the extent the recipe is followed.

### SUMMARY OF THE DISCLOSURE

This summary is provided to introduce a selection of concepts in a simplified form. These concepts are described in further detail in the detailed description of example embodiments of the disclosure below.

This summary is not intended to identify key features or essential features of the claimed subject matter, nor is it intended to be used to limit the scope of the claimed subject matter.

In accordance with one embodiment there may be provided, a semiconductor substrate processing apparatus comprising: a reactor for processing a semiconductor substrate; a valve to provide gas to the reactor for processing the substrate; a process controller operationally connected to the valve and provided with a memory to save a process recipe for processing the semiconductor substrate, the process controller being arranged and programmed to generate a valve activation signal based on the process recipe and transmit the valve activation signal to the valve to open or close the valve to provide or stop providing the gas to the reactor according to the recipe; and a valve monitor system to monitor the opening and closing of the valve.

In at least one aspect, the valve monitor system comprising: a sensor operationally coupled to the valve to sense the opening and closing of the valve and the sensor generates a valve movement signal when movement of the valve is sensed.

In at least one aspect, the valve monitor system may be operationally connected to the process controller to compare the valve activation signal and the valve movement signal with each other by subtracting the timing of the valve activation signal from the timing of the valve movement signal to determine a delay in response of the valve as shown in the equation (eq1) below. eq1) time delay = valve movement signal time - valve activation signal time.

In at least one aspect, the sensor is an optical sensor, the valve is a pneumatic valve, and wherein, the valve activation signal activates a compressed air line to the pneumatic valve to open.

In at least one aspect, the pneumatic valve has a close position mark and an open position mark, and the process controller is configured to monitor the pneumatic valve and measure the time when the pneumatic valve’s piston is at the close position mark and the time when the pneumatic valve’s piston is at the open position mark, and the process controller is further configured to calculate a delay time by subtracting the time when the piston is at the close position mark from the time when the piston is at the open position mark, and the process controller is further configured to determine the compressed air line to be pinched if the delay time is greater than a predetermined delay time.

In at least one aspect, if the time delay for a valve is equal to or less than the predetermined threshold, the time delay is defined as standard reaction time and the valve is decided as a standard reaction time valve and if the time delay for a valve is bigger than the predetermined threshold, the time delay is defined as delayed reaction time and the valve is decided as a delayed reaction time valve respectively and, the process controller also further configured to compute correction time for each delayed reaction time valve with the equation (eq2) below, eq2) correction time = delayed reaction time - standard reaction time, wherein the standard reaction time in eq2) can be an average of standard reaction time of all the standard reaction time valves or the minimum standard reaction time among the valves.

In at least one aspect, the process controller further configured to compute correction time for each delayed reaction time valve with the equation (eq3) below, eq3) correction time = delayed reaction time - predetermined threshold.

In at least one aspect, the process controller further configured to generate valve activation signal earlier than the recipe as much as the correction time for delayed reaction time valves and to generate valve activation signal according to the recipe for the standard reaction time valves.

In at least one aspect, wherein the process controller further configured to update the recipe for the delayed reaction time valves so that the valve activation signals for the delayed reaction time valves are to be generated earlier than as much as correction time in the original recipe.

In at least one aspect, the apparatus further comprising: a user interface which may receive inputs from users and display the time delays of each of the valves, wherein the user interface also can receive and update the predetermined thresholds for the valves.

In accordance with one embodiment there may be provided, a semiconductor substrate processing apparatus comprising: a reactor for processing a semiconductor substrate; a valve to provide gas to the reactor for processing the substrate; a process controller operationally connected to the valve and provided with a memory to save a process recipe for processing the semiconductor substrates, the process controller being arranged and programmed to generate a valve activation signal based on the process recipe and transmit the valve activation signal to the valve to open or close the valve to provide or stop providing the gas to the reactor according to the recipe; a valve monitor system to monitor the opening and closing of the valve, wherein the valve monitor system comprising: a sensor operationally coupled to the valve to sense the opening and closing of the valve and the sensor generates a valve movement signal when movement of the valve is sensed and a server configured to receive the valve movement signals sent from the sensor; and a user interface configured to receive input from users and to display signals.

In at least one aspect, the server further comprising: a processing unit and a memory unit, the memory unit configured to save the valve movement signal and the processing unit configured to process saved valve movement signals for displaying.

In at least one aspect, the server computes time delay for every valve using the equation (eq4) below. eq4) time delay = valve movement signal time - valve activation signal time

In at least one aspect, the server may be further configured to determine whether the received valve movement signals are good or bad based on the computed time delay, such that if time delay associated with the received valve movement signal is bigger than a predetermined threshold saved in the recipe then the valve activation signal associated with the received valve movement signal is determined to be bad, and if time delay associated with the received valve movement signal is equal to or less than a predetermined threshold saved in the recipe then the valve activation signal associated with the received valve movement signal is determined to be good.

In accordance with another embodiment there may be provided, a method to process semiconductor substrates, the method comprising: sending valve activation signals, from a process controller, to valves according to recipe; receiving valve movement signals, from sensors which are coupled to the valves, and computing, by the process controller, the time delay for all valves with equation (eq5) below, (eq5) time delay = valve movement signal time - valve activation signal time; deciding, by the process controller, for every valve whether the time delay for the valve is within a predetermined threshold and if the time delay for a valve is equal to or less than the predetermined threshold, the time delay is defined as standard reaction time and the valve is decided as a standard reaction time valve and if the time delay for a valve is bigger than the predetermined threshold, the time delay is defined as delayed reaction time and the valve is decided as a delayed reaction time valve respectively and, computing, by the controller, correction time for each delayed reaction time valve with the equation (eq6) below, (eq6) correction time = delayed reaction time - standard reaction time, wherein the standard reaction time in (eq6) can be an average of standard reaction time of all the standard reaction time valves or the minimum standard reaction time among the valves.

In at least one aspect, the correction time may be computed with equation (eq7) below, (eq7) correction time = delayed reaction time - predetermined threshold.

In at least one aspect, the method further comprising: updating the recipe with the computed correction time for the valves and sending valve activation signals, from the controller to the valves according to the updated recipe.

In at least one aspect, the method further comprising: sending valve activation signal, from the process controller to valves such that the valve activation signal sending time is the computed correction time earlier than that of the recipe.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 shows a visual graph of valve 1 & 2′s valve open and valve movement signals in time to show that the difference between valve 1 & 2 according to an embodiment of the present invention.

FIG. 2(a) illustrates signal timing change before updating slower valve (valve 2)′s value in the recipe to compensate the slow opening nature of valve 2 according to an embodiment of the present invention.

FIG. 2(b) illustrates signal timing change after updating slower valve (valve 2)′s value in the recipe to compensate the slow opening nature of valve 2 according to an embodiment of the present invention.

FIG. 3 shows a schematic view of the system according to an embodiment of the present invention.

FIG. 4(a) illustrates an example of how to send next signals for the valve operation according to an embodiment of the present invention.

FIG. 4(b) illustrates an example of how to send next signals for the valve operation according to an embodiment of the present invention.

FIG. 4(c) illustrates an example of how to send next signals for the valve operation according to an embodiment of the present invention.

FIG. 5 illustrates a schematic view of a system according to another embodiment of the present invention.

FIG. 6 illustrates another schematic view of a system that is a variant version of FIG. 4 according to another embodiment of the present invention.

FIG. 7 illustrates another schematic view of a system that is another variant version of FIG. 4 according to another embodiment of the present invention.

FIG. 8 illustrates a detailed view of server according to another embodiment of the present invention.

FIG. 9 illustrates a detailed view of process controller according to another embodiment of the present invention.

FIG. 10 illustrates a method employed in a system of FIG. 3 according to an embodiment of the present invention.

FIG. 11 illustrates another method employed in systems of FIGS. 4 - 6 according to another embodiment of the present invention.

FIG. 12 illustrates an example of a part of the recipe and the pulse values decided good or bad from the recipe according to another embodiment of the present invention.

FIG. 13(a) illustrates an example of a valve setting according to another embodiment of the present invention.

FIG. 13(b) illustrates an example of a measurements for the valve when the valve is decided to open without line pinching according to another embodiment of the present invention.

FIG. 13(c) illustrates an example of a valve opens with a pinched line.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In semiconductor substrate processes, ALD process for example, many valves may be used to control the flow of precursors to the substrate. Also, in PEALD and PECVD, RF generators may be used to provide plasma to the substrate chambers and the generators may need to be controlled with precision to provide plasma to the valves with exact timing.

The valves may need to be controlled with precision because the punctuality of valve opening, and closing may cause the timing of precursor over the substrate and the quality of the substrate as a result.

Therefore, the control mechanism of the present embodiments may be applied to valves as well as RF generators since RF generators should be equipped with punctual movement just like the valves in PEALD and/or PECVD. For convenience, valves are used for examples, but this does not limit the scope of the present embodiments.

Valves may be equipped with valve open/close mechanism. The mechanism may be such that the valves may be closed when not in use and only open when a general activation signal is received.

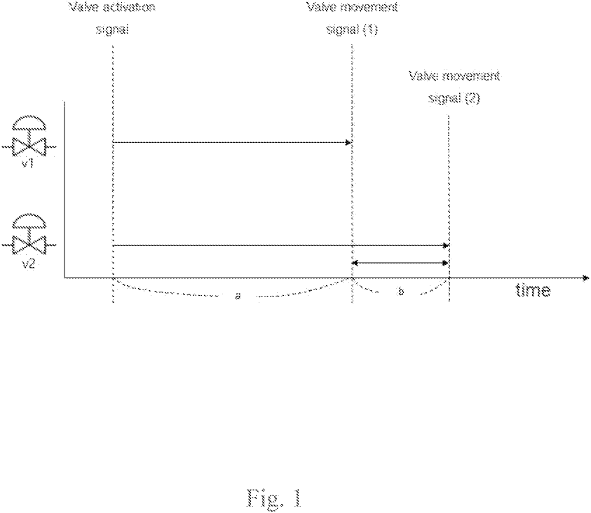

FIG. 1. shows visual graph of valve 1 & 2′s ‘valve activation signal’ and ‘valve movement signal’ in time axis to show that the difference between valve 1 & 2 according to an embodiment of the present invention. Valve activation signal may instruct the valve controller (not shown in the Figures) to open the valve so that the precursor and/or gas can flow and in the chamber for chemical reaction. Valve movement signal may instruct the valve to open, and it may be generated by sensors coupled to a valve. In semiconductor substrate processes, valves may be usually closed in normal circumstances and open only when valve activation signal is received.

Valve 1 (v1) and Valve 2 (v2) have valve activation signals at the same time but valve movement signals take different time. Valve 1 takes ‘a’ time from valve activation signal to valve movement signal while Valve 2 takes ‘a + b’ time from valve activation signal to valve movement signal which is longer than ‘a’ time. The time delay ‘b’ means that Valve 2 (v2) reacts slower than Valve 1 (v1). In this case, if v1 and v2 are used in same reaction and if the reaction should need a simultaneous opening of v1 and v2, the quality of resulting substrates is quite lower than expectation because the reaction is not enough due to the time delay of v1 and v2′s opening (and the precursors are not fully reacting). The time in this example may be measured usually in milli-second (ms) but other measurements can be possible (such as micro-second(µs) etc.).

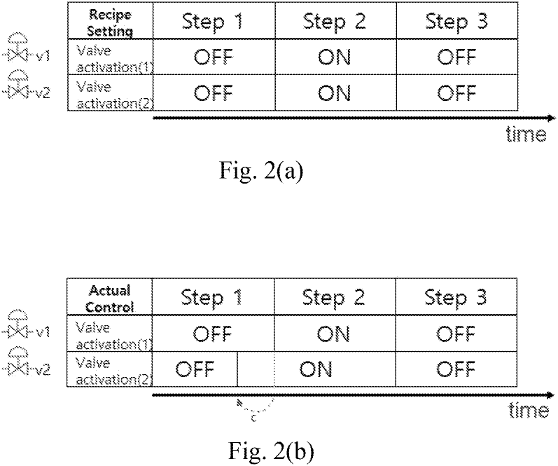

An embodiment to overcome this situation is shown in FIG. 2.

In FIG. 2(a), the original recipe is shown. A recipe is a schedule or a plan to execute for substrate processing, like when to open a certain valves, etc. In FIG. 2(a), a part of recipe for valves 1 & 2 and steps 1-3 are described. Valves 1 & 2 are to open in step 2 at the same time in the original recipe.

But, since valve 2 (v2) may react slower than valve 1 (v1) just as shown in FIG. 1, the actual reaction of valve 2 is somewhat different from the recipe.

Since v2′s reaction time is ‘b’ time slower than that of v1, v2 is instructed to open the valve ‘b’ time earlier than v1. Therefore, the length of ‘c’ time in FIG. 2(b) is the same as that of ‘b’ time in FIG. 1. ‘a’ time can be named as ‘standard reaction time’ and ‘b’ time can be named as ‘delayed reaction time’. Although ‘c’ time is usually the same as ‘b’ time, ‘c’ time is called ‘correction time’ since the valve activation signal is sent ‘c’ time (i.e. ‘b’ time) earlier than the original recipe.

The controller 10 computes the time delays for every valve by subtracting valve activation signal time (timestamp) from valve movement signal time of the valve using the equation (eq1) below.

(eq1) time delay = valve movement signal time - valve activation signal time

The controller 10 may determine that if a valve has a time delay within a predetermined threshold (in a recipe) then the valves which have standard reaction time may be decided as ‘standard reaction time valve’ and valves with delayed reaction time ‘delayed reaction time valve’. This can be done by comparing the threshold from recipe with the computed time delay for all valves.

For the new valve activation signal (‘c’ time earlier than the original recipe for v2), the recipe can be updated so that the updated recipe’s valve activation signal time is ‘c’ time earlier than that of original recipe.

Alternatively, the signal timing can be updated so that the updated valve activation signal time is ‘c’ time earlier than that of original recipe without updating the recipe itself.

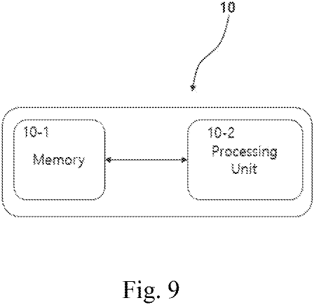

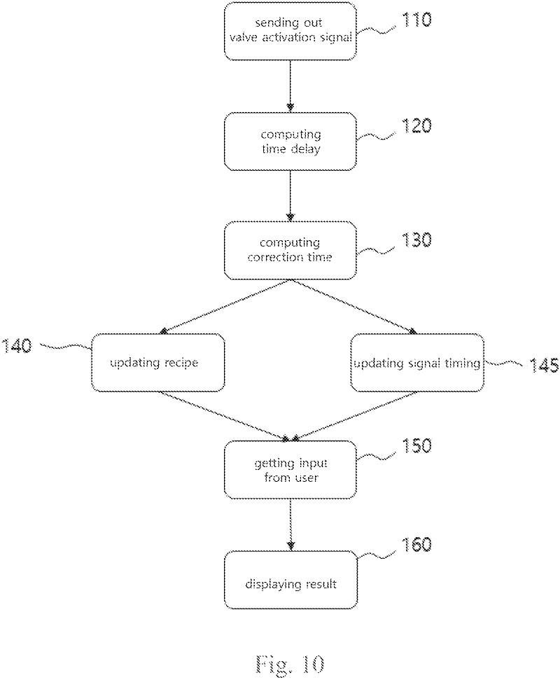

FIG. 9 shows process controller 10. Process controller 10 comprises memory 10-1 and processing unit 10-2 such as CPU used in computer systems. It should be noted that process controller 10 is a computer. Process controller 10 can save into, retrieve from and update data on its memory 10-1, can generate, send and receive signals, and can measure time between signal sending & receiving using its processing unit 10-2.

Process controller 10 (can be addressed as controller hereafter) is configured to generate signals based on the recipe saved in its memory 10-1 using its processing unit 10-2. However, process controller 10 can be more configured to generate signals even ahead of its recipe due time without updating of the recipe by using the processing unit. This is due to the process controller 10′s ability as a computing entity just like general purpose computers.

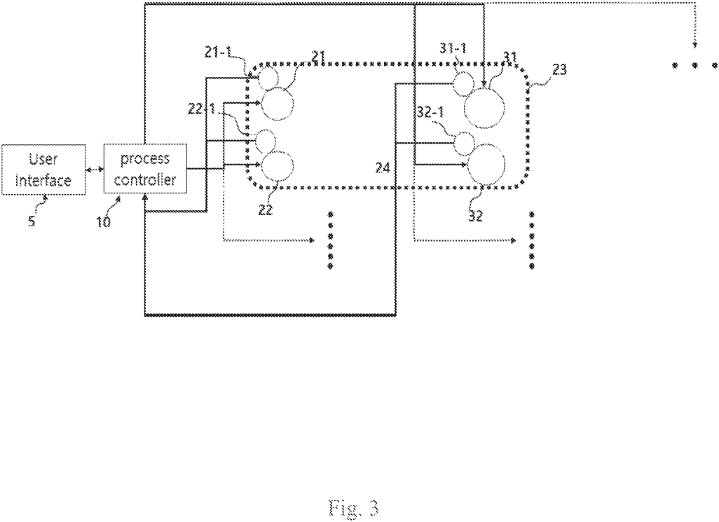

FIG. 3 shows an apparatus diagram for processing semiconductor substrates according to an embodiment of the present invention.

The apparatus comprises: controller 10, reactor 23, valves 21, 22, 31, 32, valve monitor system 21-1, 22-1, 31-1, 32-1 which may be coupled to the valves 21, 22, 31, 32, respectively, and user interface 5 and the links between the user interface 5 and controller 10 and the valves 21, 22, 31, 32 and the sensors 21-1, 22-1, 31-1, 32-1. Valve monitor system comprises a sensor 21-1, 22-1, 31-1, 32-1 operationally coupled to the valve to sense the opening and closing of the valve and the sensor generates a valve movement signal when movement of the valve is sensed.

User interface 5 may be used to get recipe inputs from users. It also can display the status of recipe execution results too. The recipe may be stored in the controller 10 and the controller 10 saves the recipe executions like valve activation signal sending time (timestamp) and valve movement signal reception time (timestamp). For convenience, time can mean timestamp in this specification.

Controller 10 may send valve activation signals according to the recipe stored in it. For the purposes controller 10 can store data (like recipe), generate and send out signals, receive signals with time and save the signals in and out with time. Controller 10 also may send out the saved data (with time) to user interface for displaying them.

Valves 21, 22, 31, 32 can be valves, RF generators or anything that need high time precision control that have the capabilities of opening and closing with timing instruction. The number of valves can be one or more than one.

Valve monitor system 21-1, 22-1, 31-1, 32-1 may be coupled to valves respectively. The valves used in semiconductor processing may be usually closed. RF generators do not generate plasma in the same respect. Valves open and generators generate plasma only when they receive activation signals. The valve monitor system (sensor) 21-1, 22-1, 31-1, 32-1 measures the opening (and of course the closing) time of the valve to which they are coupled. Also, the valve monitor system (sensor) 21-1, 22-1, 31-1, 32-1 may be also configured to send valve movement signal to the controller 10 only when they sense the opening of the valve to which they are coupled.

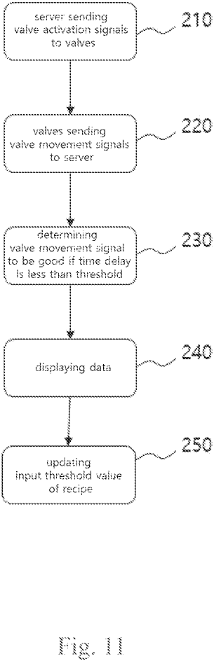

FIG. 10. depicts a diagram for the method according to an embodiment of the present invention. Process recipe may be already stored in the controller 10. The recipe dictates the times of the signals which instruct the valves to open.

First, the controller 10 sends out valve activation signals to valves according to recipe (110). Then the valves, in response to the signals, open and the moment they are open the sensors 21-1, 22-1, 31-1, 32-1 send back the valve movement signals to the controller 10 indicating that the valve each of them attaches to is open. The controller 10 receives the valve movement signals from the sensors 21-1, 22-1, 31-1, 32-1 and compute all the time delays of each valve. The time delays for every valve can be computed by subtracting valve activation signal time (timestamp) from valve movement signal time (120) of the valve like the equation (eq2) shown below.

(eq2) time delay = valve movement signal time - valve activation signal time

It should also be noted that the valve monitor system (sensor) 21-1, 22-1, 31-1, 32-1 may be operationally connected to the controller 10.

After the time delay calculated, the controller 10 decides for every valve whether the time delay for the valve may be within a predetermined threshold and if the time delay for a valve may be equal to or less than the predetermined threshold, the time delay may be defined as standard reaction time and the valve may be decided as a standard reaction time valve and if the time delay for a valve may be bigger than the predetermined threshold, the time delay may be defined as delayed reaction time and the valve may be decided as a delayed reaction time valve respectively and, the controller 10 also computes correction time for each delayed reaction time valve with the equation (eq3) below (130),

(eq3) correction time = delayed reaction time - standard reaction time

Alternatively, the controller may be further configured to compute correction time for each delayed reaction time valve with the equation (eq4) below,

(eq4) correction time = delayed reaction time - predetermined threshold

The controller 10 also updates the recipe such that the computed correction time for each valve replaces the original recipe’s valve activation signal timing and sends the valve activation signals according to the updated recipe (140).

Or alternatively, the signal timing can be updated so that the updated valve activation signal time may be ‘correction time’ earlier than that of recipe without updating the recipe itself (145).

The user interface 5 also can get inputs from users for each valve’s threshold to change the recipe’s threshold values for each valve (150). The user interface 5 can also display the result of valve activation signals, valve movement signals and the data such as the recipe (160). The user interface 5 may display the data before or after it gets inputs. It means that displaying and getting input in (150) & (160) don’t need to be executed in sequence and (160) can be executed before (150).

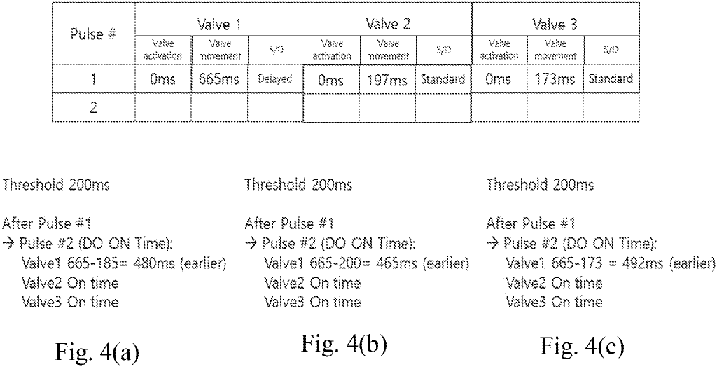

FIG. 4. shows an example with values of the embodiment. In FIG. 4, the tables show the valves 1-3 and the valve activation time and valve movement time for each of the valve.

As shown, valve 1, 2 and 3′s valve activations are the same (0 ms). But valve 1′s valve movement signal time is 665 ms while valve 2 & valve 3′s valve movement signal times are 197 ms & 173 ms, respectively. However, the threshold is set to 200 ms. Therefore, valve 1 is decided to be delayed reaction time valve since the ‘valve movement signal’ time - ‘valve activation signal’ time value is larger than threshold (200 ms) while valve 2 and valve 3 are decided to be standard reaction time valves since both ‘valve movement signal’ time - ‘valve activation signal’ time values are less than 200 ms (197 & 173 ms, respectively).

For the controller 10 to decide the correction time for each valve (using eq2 below), ‘standard reaction time’ should be calculated since either valve 2′s standard reaction time (197 ms) or valve 3′s standard reaction time (173 ms) can be both ‘standard reaction time’ for the (eq3).

For the ‘standard reaction time’ in equation (eq3), there may be 3 alternative ways to set the value.

Firstly, an average value of all the standard reaction time can be used in equation eq2. Since average value of 197 & 172 is 185, FIG. 4. (a) shows valve 1′s valve activation signal time updated to 480 (= 665 - 185) ms. This means that valve 1′s valve activation signal is generated and sent 480 ms earlier than the recipe.

Secondly, the threshold of the recipe can be used as the ‘standard reaction time’ in (eq3). In FIG. 4(b), valve 1′s valve activation time is updated into 465 (665-200) ms. This means that valve 1′s valve activation signal is generated and sent 465 ms earlier than the original recipe.

Thirdly, the minimum standard reaction time among all the standard reaction time may be used for the ‘standard reaction time’ in (eq3). In FIG. 4(c), valve 1′s valve activation time may be updated into 492 (665-173) ms. This means that valve 1′s valve activation signal may be generated and sent 492 ms earlier than the original recipe.

The controller 10 may generate and send the valve activation signals for the delayed reaction time valves without updating the recipe. This can be done because the controller 10 can be a computer in its functions and every valve activation signals sent and valve movement signals received may be memorized in its own memory so that the next signal can be deduced without updating the original recipe.

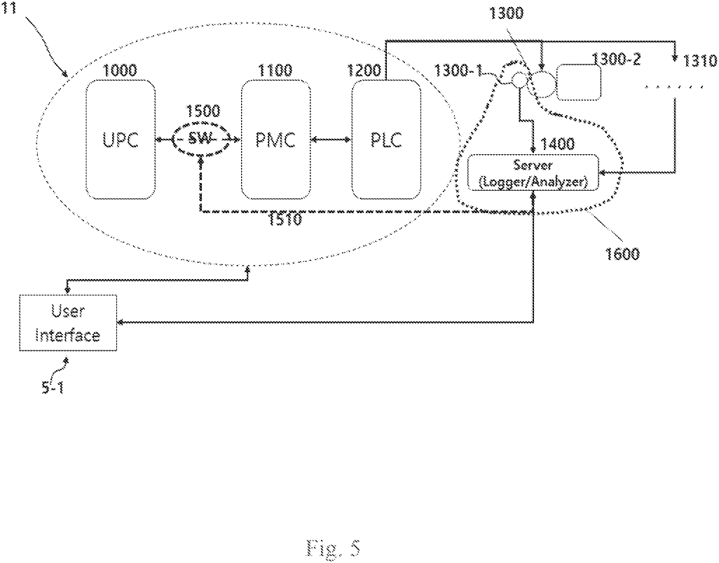

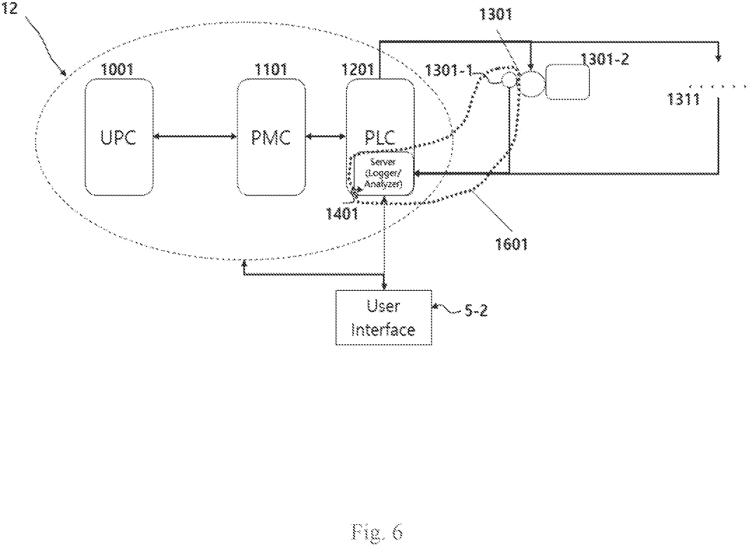

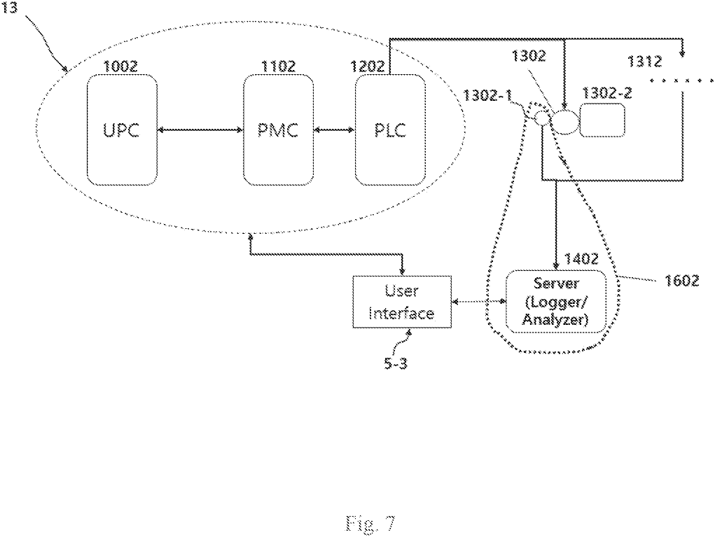

In FIGS. 5-7 show 3 different embodiments of apparatus of the present invention.

The FIGs have the same features with different set-ups. The apparatus comprises process controller 11, 12, 13, valves 1300, 1310, 1301, 1311, 1302, 1312, and a valve monitor system 1600, 1601, 1602, and reactor 1300-2, 1301-2, 1302-2.

The valve monitor system 1600, 1601, 1602 comprises sensor 1300-1, 1301-1, 1302-1, and server 1400, 1401, 1402.

The process controller 11, 12, 13 (‘controller’ from now on) comprises UPC (Unique Platform Controller) 1000, 1001, 1002, PMC (Process Module Controller) 1100, 1101, 1102, and PLC (Programmable Logic Controller) 1200, 1201, 1202. UPC, PMC and PLC may be computers with local memories and processing unit. In this context, UPC, PMC and PLC may be controllers with computing capabilities, I/O capabilities and memory capabilities so that they may be thought as computers in those respects. The names of UPC, PMC & PLC may just represent the functions of each controller and do not mean any specifics.

UPC 1000, 1001, 1002 may be a controller for saving & scheduling recipe. PMC 1100, 1101, 1102 may be a controller which generates valve activation signals. PLC 1200, 1201, 1202 may be an I/O controller which links the controller 11, 12, 13 to the valves 1300, 1310, 1301, 1311, 1302, 1312. The number of valves may be one or more than one.

Sensor may be installed on a valve for measuring the opening and closing of the valve and when movements of the valve is sensed, send the valve movement signal to the server 1400, 1401, 1402. The sensors can be optical or electrical, precise enough to measure the slight movements of the valves.

Server 1400, 1401, 1402 may be for saving the valve movement signals from the sensors and also for analyzing the data for user display. The server can save valve movement signals with the timing (timestamp) and the saved data can be analyzed in the server for user display.

It should also be noted that UPC, PMC and PLC may be processors which can be regarded as a computer system. In fact, UPC, PMC and PLC all work in concert with each other so that one can regard all 3 of them to comprise a single controller (which can be also regarded as a computer system).

User interface 5-1, 5-2, 5-3 can get inputs (i.e., threshold values) or can display the data saved in the controller 11, 12, 13 and/or server 1400, 1401, 1402. The values input from the user interface 5-1, 5-2, 5-3 can be updated into the controller 11, 12, 13.

FIG. 5. depicts one aspect of another embodiment of the present invention.

In addition to the above already described features, FIG. 5 has switch 1500 which controls the link between UPC 1000 and PMC 1100. PLC 1200 may be directly connected to the valves and the sensors 1300-1 may send the valve movement signals to the valve monitor system 1600′s server 1400 for saving and analyzing. User interface 5-1 may be connected to the controller 11 and the server 1400 so that it can display the analyzed data saved in server 1400 or can input the info into the controller 11.

FIG. 6 depicts another aspect of another embodiment of the present invention.

In this aspect, the valve monitor system 1601′s server 1401 may be placed within the controller 12 for overall system performance.

FIG. 7 depicts another aspect of another embodiment of the present invention. In this, the apparatus’ configuration is almost the same to FIG. 5 except that the server 1402 does not have direct any connection with the controller 13.

The differences between system overviews of FIGS. 5-7 are due to the apparatus’ capabilities and for the purpose of smooth operation of the apparatus.

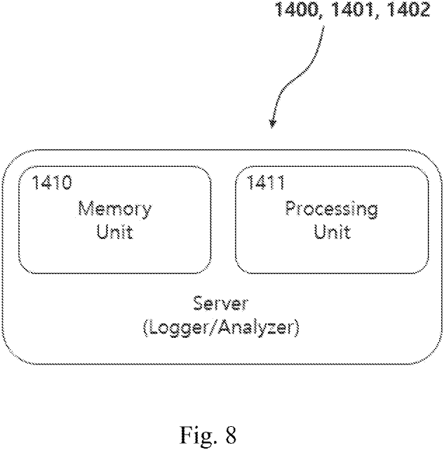

FIGS. 8 & 9 each depicts server 1400, 1401, 1402 and controller 10. As stated before, server 1400, 1401, 1402 and controller 10 may be all equipped with memory and processing unit respectively, effectively making them independent computer systems.

FIG. 11 shows a flowchart for a system among FIGS. 5-7.

A method which runs on the apparatus in FIGS. 5 - 7 is as follows.

As stated, recipe can be already stored and retrieved for execution in the controller 11, 12, 13 (in UPC 1000, 1001, 1002 specifically).

First, the controller 11, 12, 13 sends valve activation signals (generated in PMC 1100, 1101, 1102 and sent through PLC 1200, 1201, 1202 more specifically; controller will be used from now on instead of UPC, PMC or PLC) to the connected valves and the valve activation signals may be generated according to recipe saved (210).

Once the valves 1300, 1301, 1302 respond, the sensors 1300-1, 1301-1, 1302-1 of the valve monitor system 1600, 1601, 1602 which may be coupled to the valves 1300, 1301, 1302 send valve movement signals to the server 1400, 1401, 1402 and the server 1400, 1401, 1402 saves them (220).

The server 1400, 1401, 1402 then computes time delay for every valve using the equation (eq5) below.

(eq5) time delay = valve movement signal time - valve activation signal time

Also the server 1400, 1401, 1402 determines whether the received valve movement signals may be good or bad based on the computed time delay.

The determination process may be such that if the time delay associated with the received valve movement signal may be bigger than a predetermined threshold (which is saved in recipe in the controller 11, 12, 13) then the valve activation signal associated with the received valve movement signal may be determined to be bad.

And if time delay associated with the received valve movement signal is equal to or less than the predetermined threshold then the valve activation signal associated with the received valve movement signal may be determined to be good (230).

After the determination of good or bad, this data can be stored to be displayed in user interface 5-1, 5-2, 5-3.

After the computing and determining, the stored data in the server 1400, 1401, 1402 can be displayed via user interface 5-1, 5-2, 5-3. The controller 11, 12, 13 can also send data to the user interface 5-1, 5-2, 5-3 so that the data (i.e. recipe) can be displayed to users also (240).

The value of predetermined threshold of valves may differ from each valve since different valves have different levels of criticality as well as different timing delays associated with itself. Therefore, it may be needed to update or change the predetermined threshold of valves in separate, independently among themselves.

For this purpose, new threshold values for each valve may be input by user interface 5-1, 5-2, 5-3 from users and the controller 11, 12, 13 updates the input threshold values in the recipe (250).

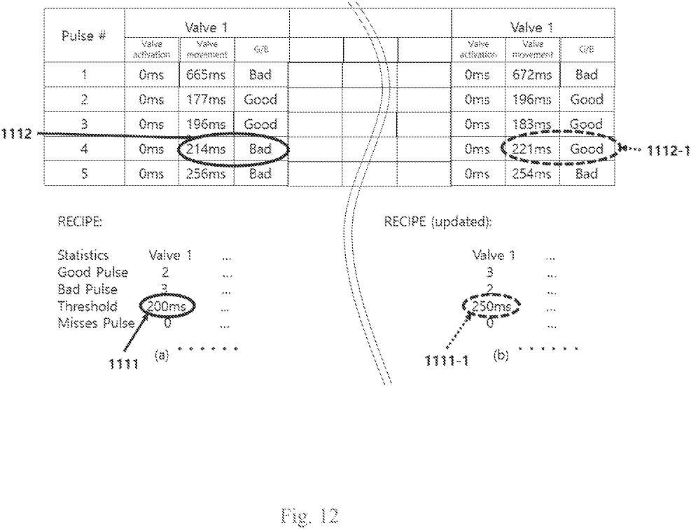

With FIG. 12, an example for the systems depicted in FIGS. 5-7 and the method depicted in FIG. 11 is demonstrated.

A partial recipe (a) before an update and (b) after an update and the related table display for valve 1 is shown in FIG. 12.

At first, in the recipe (a), the threshold is set to 200 ms which means that any time delay (i.e. valve movement signal - valve activation signal) larger than 200 ms would be decided to be bad.

The table above (a) shows that the valve activation signal times are all 0 ms while valve movement signal times are all different. More specifically, Pulse #1, #4 & #5 have 665 ms, 214 ms and 265 ms as time delay respectively. The time delay of #1, #4 & #5 is larger than 200 ms which means that they are bad. (Which is shown in G/B[Good/Bad] column) The other Pulses #2 & #3 are good because their time delay is smaller than the threshold (200 ms).

Now if we turn our attention to (b), we can see that the Good/Bad ratio of valve 1 is changed because the threshold for valve 1 is changed into 250 ms (1111-1) not 200 ms (1111).

It should also be noted that this threshold change can be done by threshold input from the user interface 5-1, 5-2, 5-3 and updating of the recipe in the controller 11, 12, 13.

In (b), since the threshold is changed/updated into 250 ms, the Pulse #4 which was decided to be bad (1112) in the original (before the update) recipe is now decided to be good (1112-1).

This is an example of how the data stored in the server 1400, 1401, 1402 may be displayed in the user interface 5-1, 5-2, 5-3 while graphical display can be also possible.

The methods described above, i.e., 110 - 160 and in FIG. 10, can be written in a set of instructions, and they can be stored on a non-transitory, computer-readable and tangible medium, which can be executed by a processor of a computer system so that the methods can be carried out by the computer system’s processor on the computer system. Also the methods described above, i.e., 210 - 250 and in FIG. 11, can be written in a set of instructions, and they can be stored on a non-transitory, computer-readable and tangible medium, which can be executed by a processor of a computer system so that the methods can be carried out by the computer system’s processor.

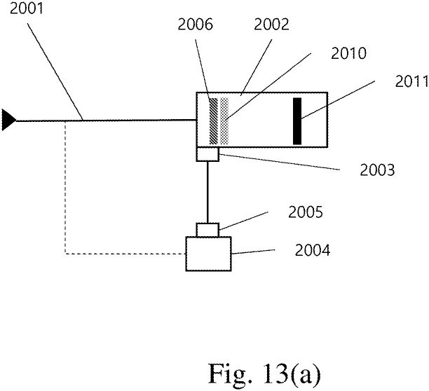

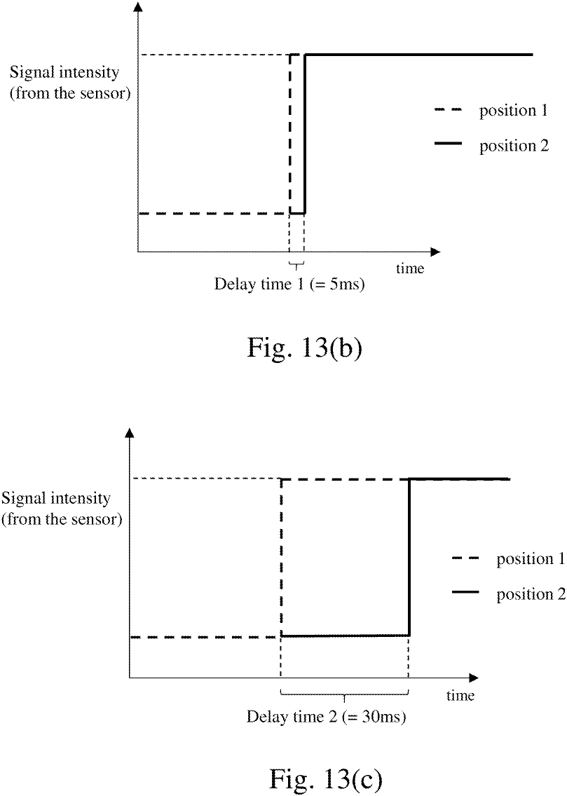

In FIG. 13, another embodiment of this disclosure is illustrated.

There are sometimes when the valve itself may function normally but the surrounding parts malfunctioning.

Generally, pneumatic valves 2002 may be a very essential and critical component in ALD process. They may be used to enable the gas to flow through the line when open and prevent the flow of gas through the line when closed.

The opening and closing of pneumatic valve may be actuated by a compressed air line 2001. For a normally closed valve, when compressed air is input to the valve actuator (not drawn), it pushes the pneumatic valve’s piston 2006 to move forward from a close position mark 2010 to an open position mark 2011. In absence of compressed air, the pneumatic valve is usually closed.

When the compressed air input line 2001 may be pinched/restricted, compressed air supply to valve actuator is restricted and hence the pneumatic valve 2002 takes a longer time to open or in worst case never opens, although it is commanded to open. Pneumatic valve 2002 with a longer time than a predetermined delay time to open or not opening when instructed by process recipe could result in bad wafer quality and thus production loss.

An optical sensor 2003 may be configured to determine whether the pneumatic valve 2002 is open or closed. Process controller 2004 is also configured to read the optical signal (for example, light intensity or electrical intensity) from the optical sensor 2003.

The process controller 2004 may be configured to send out valve activation signal to activate the compressed air line 2001 to input the compressed air to the pneumatic valve 2002 to open. The process controller 2004 may be further configured to determine whether the pneumatic valve 2002 is closed (at close position mark 2010) or open (at open position mark 2011).

The close position mark 2010 may be a position of the valve’s piston when the valve 2002 is closed and the open position mark 2011 may be a position of the valve’s piston when the valve 2002 is open or any other position decided by operator.

The process controller 2004 may be configured to measure the time when the pneumatic valve 2002 is at the close position mark 2010 and the time when the pneumatic valve 2002 is at the open position mark 2011 from the receipt time of valve activation signal by the process controller 2004.

The process controller 2004 may also be configured to compute the time difference (delay time) between the time when the pneumatic valve 2002′s piston 2006 is at the open position mark 2011 and the time when the pneumatic valve 2002′s piston 2006 is at the close position mark 2010 by subtracting the latter (time at open position) from the former (time at close position).

This delay time is used to decide whether the compressed air line 2001 is normal (normal operation) or the compressed air line 2001 is pinched or malfunctioning by comparing it with a predetermined delay value in the process controller 2004.

If the measured delay time (delay time value) is equal to or less than the predetermined delay value, the compressed air line 2001 may be determined to be operating normally, and if the delay time value is greater than the predetermined delay value, the compressed air line 2001 may be determined to be pinched or abnormal.

FIG. 13(a) is a simplified overview of the present disclosure with an optical sensor 2003. The compressed air line 2001 is connected to the pneumatic valve 2002 and the optical sensor 2003 is configured to measure how much the valve is open. Process controller 2004 is communicably connected to the sensor 2003 but it also may be connected to the compressed air line 2001 for valve open with a valve activation signal. Additional signal amplifier 2005 could be used with the process controller 2004 for better signal resolution from the optical sensor 2003.

FIG. 13(b) illustrates a case when the delay time (‘Delay time 1’) is smaller than a predetermined delay value, i.e. 10 ms. The signal intensity of y-axis is the intensity of the signal from the optical sensor 2003 received by the process controller 2004. This signal could be light, electricity or whatever that can be measured. The signal amplifier 2005 could be attached to the process controller 2004 for better readout of the signal from the sensor 2003.

Since delay time 1 (5 ms) is smaller than the predetermined delay value (10 ms), the compressed air line 2001 is determined to be normal.

FIG. 13(c) illustrates a case when the delay time (‘Delay time 2’) is greater than a predetermined delay value (10 ms). Since delay time 2 (30 ms) is greater than the predetermined delay value (10 ms), the compressed air line 2001 is determined to be pinched and abnormal.

If the valve 2002 never opens (meaning that the valve never opens up to open position), the delay time is getting bigger indefinitely while waiting for the valve 2002 to open. A second predetermined delay time value might be used for the process controller 2004 to stop measuring the valve open time and determine that the compressed air line 2001 is pinched instantly for saving time and improving productivity.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A semiconductor substrate processing apparatus comprising:
a reactor for processing a semiconductor substrate;
a valve to provide gas to the reactor for processing the substrate;
a process controller operationally connected to the valve and provided with a memory to save a process recipe for processing the semiconductor substrate, the process controller being arranged and programmed to generate a valve activation signal based on the process recipe and transmit the valve activation signal to the valve to open or close the valve to provide or stop providing the gas to the reactor according to the recipe; and
a valve monitor system to monitor the opening and closing of the valve.

2. The apparatus according to claim 1, wherein the valve monitor system comprising: a sensor operationally coupled to the valve to sense the opening and closing of the valve and the sensor generates a valve movement signal when movement of the valve is sensed.

3. The apparatus according to claim 2,
wherein the valve monitor system may be operationally connected to the process controller to compare the valve activation signal and the valve movement signal with each other by subtracting timing of the valve activation signal from timing of the valve movement signal to determine a delay in response of the valve as shown in equation (eq1) below,
$$\text{time delay = valve movement signal time} - \text{valve activation signal time}$$
.

4. The apparatus according to claim 2, wherein
the sensor is an optical sensor, the valve is a pneumatic valve, and wherein,
the valve activation signal activates a compressed air line to the pneumatic valve to open.

5. The apparatus according to claim 4, wherein
The pneumatic valve has a close position mark and an open position mark, and
the process controller is configured to monitor the pneumatic valve and measure the time when the pneumatic valve’s piston is at the close position mark and the time when the pneumatic valve’s piston is at the open position mark, and the process controller is further configured to calculate a delay time by subtracting the time when the piston is at the close position mark from the time when the piston is at the open position mark, and
the process controller is further configured to determine the compressed air line to be pinched if the delay time is greater than a predetermined delay time.

6. The apparatus according to claim 3, wherein,
if the time delay for the valve is equal to or less than a predetermined threshold, the time delay is defined as standard reaction time and the valve is decided as a standard reaction time valve and if the time delay for a valve is bigger than the predetermined threshold, the time delay is defined as delayed reaction time and the valve is decided as a delayed reaction time valve respectively and,
the process controller also further configured to compute correction time for each delayed reaction time valve with equation (eq2) below,
$$\text{correction time = delayed reaction time} - \text{standard reaction time,}$$
wherein the standard reaction time in eq2) can be an average of standard reaction time of all the standard reaction time valves or the minimum standard reaction time among the valves.

7. The apparatus according to claim 6, wherein the process controller further configured to compute correction time for each delayed reaction time valve with equation (eq3) below,
$$\text{correction time = delayed reaction time} - \text{predetermined threshold}$$
.

8. The apparatus according to claim 6, wherein the process controller further configured to generate valve activation signal earlier than the recipe as much as the correction time for delayed reaction time valves and to generate valve activation signal according to the recipe for the standard reaction time valves.

9. The apparatus according to claim 7, wherein the process controller further configured to update the recipe for the delayed reaction time valves so that the valve activation signals for the delayed reaction time valves are to be generated earlier than as much as correction time in the original recipe.

10. The apparatus according to claim 3, further comprising:
a user interface which may receive inputs from users and display the time delays of each of the valves, wherein the user interface also can receive and update the predetermined thresholds for the valves.

11. A semiconductor substrate processing apparatus comprising:
a reactor for processing a semiconductor substrate;
a valve to provide gas to the reactor for processing the substrate;
a process controller operationally connected to the valve and provided with a memory to save a process recipe for processing the semiconductor substrates, the process controller being arranged and programmed to generate a valve activation signal based on the process recipe and transmit the valve activation signal to the valve to open or close the valve to provide or stop providing the gas to the reactor according to the recipe;
a valve monitor system to monitor the opening and closing of the valve, wherein the valve monitor system comprising: a sensor operationally coupled to the valve to sense the opening and closing of the valve and the sensor generates a valve movement signal when movement of the valve is sensed and a server configured to receive the valve movement signals sent from the sensor; and
a user interface configured to receive input from users and to display signals.

12. The apparatus according to claim 11, wherein the server further comprising: a processing unit and a memory unit, the memory unit configured to save the valve movement signal and the processing unit configured to process saved valve movement signals for displaying.

13. The apparatus according to claim 11, wherein the server computes time delay for every valve using equation (eq4) below,
$$\text{time delay = valve movement signal time} - \text{valve activation signal time}$$
.

14. The apparatus according to claim 11, wherein the server may be further configured to determine whether the received valve movement signals are good or bad based on the computed time delay, such that if time delay associated with the received valve movement signal is bigger than a predetermined threshold saved in the recipe then the valve activation signal associated with the received valve movement signal is determined to be bad, and if time delay associated with the received valve movement signal is equal to or less than a predetermined threshold saved in the recipe then the valve activation signal associated with the received valve movement signal is determined to be good.

15. A method to process semiconductor substrates, the method comprising:
sending valve activation signals, from a process controller, to valves according to recipe;
receiving valve movement signals, from sensors which are coupled to the valves, and computing, by the process controller, the time delay for all valves with equation (eq5) below,
$$\text{time delay = valve movement signal time - valve activation signal time;}$$
deciding, by the process controller, for every valve whether the time delay for the valve is within a predetermined threshold and if the time delay for a valve is equal to or less than the predetermined threshold, the time delay is defined as standard reaction time and the valve is decided as a standard reaction time valve and if the time delay for a valve is bigger than the predetermined threshold, the time delay is defined as delayed reaction time and the valve is decided as a delayed reaction time valve respectively and, computing, by the controller, correction time for each delayed reaction time valve with the equation (eq6) below,
$$\text{correction time = delayed reaction time} - \text{standard reaction time,}$$
wherein the standard reaction time in (eq6) can be an average of standard reaction time of all the standard reaction time valves or the minimum standard reaction time among the valves.

16. The method according to claim 15, wherein the correction time may be computed with equation (eq7) below,
$$\text{correction time = delayed reaction time} - \text{predetermined threshold}$$
.

17. The method according to claim 15, further comprising:
updating the recipe with the computed correction time for the valves and sending valve activation signals, from the controller to the valves according to the updated recipe.

18. The method according to claim 15, further comprising:
sending valve activation signal, from the process controller to valves such that the valve activation signal sending time is the computed correction time earlier than that of the recipe.
